(19) United States
(12) Patent Application Publication
(10) Pub. No.: US 2026/0011641 A1
(43) Pub. Date: Jan. 8, 2026

(54) BACKSIDE VIA TO POWER RAIL VIA CONNECTION

(71) Applicant: International Business Machines Corporation, Armonk, NY (US)

(72) Inventors: HUIMEI ZHOU, Albany, NY (US); Ravikumar Ramachandran, Pleasantville, NY (US); Ruilong Xie, Niskayuna, NY (US); Xiaoming Yang, Clifton Park, NY (US); LEI ZHUANG, Ridgefield, CT (US); MIAOMIAO WANG, Albany, NY (US)

(21) Appl. No.: 18/765,691

(22) Filed: Jul. 8, 2024

(51) Int. Cl. H01L 23/528; H01L 21/768; H01L 23/48; H01L 23/522; H01L 27/088; H01L 29/06; H01L 29/775; H01L 29/786

(52) U.S. Cl. CPC H01L 23/5286; H01L 21/76877; H01L 23/481; H01L 23/5226; H10D 84/83; H10D 30/43; H10D 30/6757; H10D 62/115; H10D 62/121

(57) ABSTRACT

Embodiments of present invention provide a semiconductor structure. The semiconductor structure includes a first and a second transistor; a power rail via between the first and the second transistor; and a backside via below the power rail via and below the first and the second transistor, where the backside via has a first portion directly contacting the power rail via and a second portion around the first portion, and a top surface of the first portion is above a top surface of the second portion. A method of forming the same is also provided.

### BACKGROUND

The present application relates to manufacturing of semiconductor integrated circuits. More particularly, it relates to forming a backside via to power rail via connection and the structure formed thereby.

As semiconductor industry moves towards smaller node, backside power distribution network (BSPDN) is introduced as a mean to further increase density of devices in a chip by moving some functions such as power distribution to the backside of the chip while leaving mostly signal routing functions at the frontside of the chip.

Generally, BSPDN is designed to provide power to backside power rail (BSPR) at the backside of the chip, and in-turn the BSPR provides the power from the BSPDN to active front-end-of-line (FEOL) devices such as, for example, field-effect-transistors (FETs) through power rail via. The power rail via is usually placed between active devices, often in the cell boundary area, where the tight spacing between active devices makes it difficult to form backside via contacting the power rail via without causing short to, for example, source/drain regions of the active devices nearby.

### SUMMARY

Embodiments of present invention provide a semiconductor structure. The semiconductor structure includes a first and a second transistor; a power rail via between the first and the second transistor; and a backside via below the power rail via and below the first and the second transistor, where the backside via has a first portion directly underneath and contacting the power rail via and a second portion surrounding the first portion, and a top surface of the first portion is above a top surface of the second portion.

In one embodiment, the top surface of the second portion of the backside via is covered by a protective dielectric layer; and a sidewall of the backside via and an outer sidewall of the protective dielectric layer are covered by a dielectric liner.

In another embodiment, a lower portion of the power rail via that directly contacts the backside via is directly surrounded by an inter-level dielectric (ILD) layer, and a portion of the ILD layer is surrounded by the dielectric liner.

In yet another embodiment, the top surface of the first portion of the backside via is higher than a bottom surface of the ILD layer.

In one embodiment, the power rail via has a lower portion directly contacting the backside via and a middle portion above the lower portion of the power rail via, the lower portion of the power rail via is directly surrounded by the dielectric liner, and the middle portion of the power rail via is directly surrounded by an inter-level dielectric (ILD) layer, wherein the ILD layer is above the dielectric liner and has a bottom surface that is above the top surface of the first portion of the backside via.

In another embodiment, a top surface of the protective dielectric layer is above the top surface of the first portion of the backside via and is covered by the dielectric liner.

In one embodiment, the power rail via comprises a conductive core and a core liner, the core liner lines the conductive core at a sidewall of the power rail via.

In another embodiment, the first and the second transistor include, respectively, a first and a second gate and, respectively, a first and a second source/drain region, and wherein the power rail via extends from a first region between the first and the second gate and to a second region between the first and the second source/drain region.

Embodiments of present invention provide a method of forming a semiconductor structure. The method includes forming a power rail via between a first and a second transistor, the power rail via including a conductive core surrounded by a core liner, a lower section of the power rail via being surrounded by an inter-level dielectric (ILD) layer, the ILD layer being embedded in a substrate; creating an opening in the substrate from a backside of the substrate, the opening extends above a bottom surface of the power rail via to surround a lower portion of the lower section of the power rail via; lining the opening with a dielectric liner; removing the core liner of the power rail via to expose a bottom surface of the conductive core of the power rail via; and filling the opening with a conductive material, thereby forming a backside via contacting the conductive core of the power rail via.

According to one embodiment, the method further includes depositing a protective layer in the opening above the dielectric liner; recessing the protective layer to expose a portion of the dielectric liner directly underneath the power rail via; and selectively removing the exposed portion of the dielectric liner to expose the core liner at the bottom surface of the conductive core of the power rail via.

In one embodiment, the selectively removal of the exposed portion of the dielectric liner also exposes a bottom surface of the ILD layer.

In one embodiment, creating the opening includes removing a portion of the substrate surrounding the ILD layer such that the dielectric liner lines a portion of sidewalls of the ILD layer.

In another embodiment, creating the opening includes removing a portion of the substrate and a portion of the ILD layer such that the dielectric liner lines sidewalls of a lower portion of the power rail via.

In yet another embodiment, creating the opening includes removing a portion of the substrate that is directly underneath the first and the second transistor.

### BRIEF DESCRIPTION OF THE DRAWINGS

The present invention will be understood and appreciated more fully from the following detailed description of embodiments of present invention, taken in conjunction with accompanying drawings of which:

FIGS. 1A, 1B, and 1C to FIGS. 7A, 7B, and 7C are demonstrative illustrations of cross-sectional views of a semiconductor structure at various steps of manufacturing thereof according to embodiments of present invention;

FIG. 8 is a demonstrative illustration of a simplified top view of a semiconductor structure illustrating locations of cross-section made in FIGS. 1A, 1B, 1C to FIGS. 7A, 7B, and 7C according to various embodiments of present invention; and

FIG. 9 is a demonstrative illustration of a flow-chart of a method of manufacturing a semiconductor structure according to embodiments of present invention.

It will be appreciated that for simplicity and clarity purpose, elements shown in the drawings have not necessarily been drawn to scale. Further, and if applicable, in various functional block diagrams, two connected devices and/or elements may not necessarily be illustrated as being connected. In some other instances, grouping of certain elements in a functional block diagram may be solely for the purpose of description and may not necessarily imply that they are in a single physical entity, or they are embodied in a single physical entity.

### DETAILED DESCRIPTION

In the below detailed description and the accompanying drawings, it is to be understood that various layers, structures, and regions shown in the drawings are both demonstrative and schematic illustrations thereof that are not drawn to scale. In addition, for the ease of explanation, one or more layers, structures, and regions of a type commonly used to form semiconductor devices or structures may not be explicitly shown in a given illustration or drawing. This does not imply that any layers, structures, and regions not explicitly shown are omitted from the actual semiconductor structures. Furthermore, it is to be understood that the embodiments discussed herein are not limited to the particular materials, features, and processing steps shown and described herein. In particular, with respect to semiconductor processing steps, it is to be emphasized that the descriptions provided herein are not intended to encompass all of the processing steps that may be required to form a functional semiconductor integrated circuit device. Rather, certain processing steps that are commonly used in forming semiconductor devices, such as, for example, wet cleaning and annealing steps, are purposefully not described herein for economy of description.

It is to be understood that the terms “about” or “substantially” as used herein with regard to thicknesses, widths, percentages, ranges, etc., are meant to denote being close or approximate to, but not exactly. For example, the term “about” or “substantially” as used herein implies that a small margin of error may be present such as, by way of example only, 1% or less than the stated amount. Likewise, the terms “on”, “over”, or “on top of” that are used herein to describe a positional relationship between two layers or structures are intended to be broadly construed and should not be interpreted as precluding the presence of one or more intervening layers or structures.

Moreover, although various reference numerals may be used across different drawings, the same or similar reference numbers are used throughout the drawings to denote the same or similar features, elements, or structures, and thus detailed explanations of the same or similar features, elements, or structures may not be repeated for each of the drawings for economy of description. Labelling for the same or similar elements in some drawings may be omitted as well in order not to overcrowd the drawings.

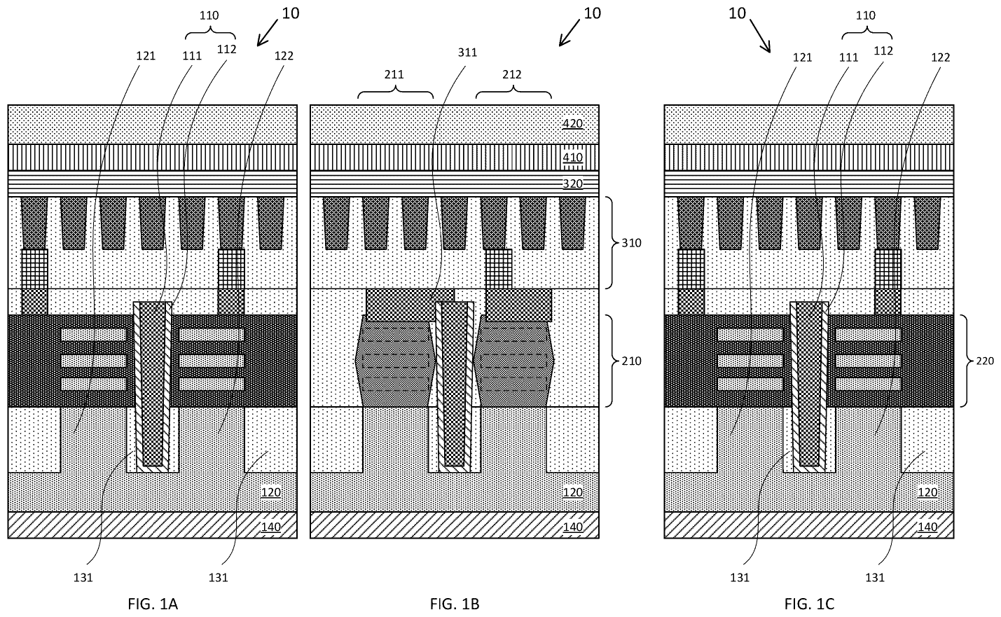

FIGS. 1A, 1B, and 1C are demonstrative illustrations of different cross-sectional views of a semiconductor structure at a step of manufacturing thereof according to embodiments of present invention. As a non-limiting example, a semiconductor structure 10 may be illustrated to include, for example, a first and a second transistor, such as a first and a second nanosheet transistor, and embodiments of present invention provide forming a backside via that contacts a power rail via where the power rail via is formed, for example, in a cell boundary area between the first and the second nanosheet transistor.

More specifically, FIG. 1A illustrates a cross-sectional view of the semiconductor structure 10, where the cross-section is made across a first and a second gate of the first and the second nanosheet transistor, respectively, in a first direction along a width of the first and the second gate; FIG. 1B illustrates a cross-sectional view of the semiconductor structure 10, where the cross-section is made across a first and a second source/drain region of the first and the second nanosheet transistor, respectively, in a second direction along a width of the first and the second source/drain region, and thus parallel to the first direction. FIG. 1C is a cross-sectional view of the semiconductor structure 10 at a same cross-section as that illustrated in FIG. 1A but for a different embodiment.

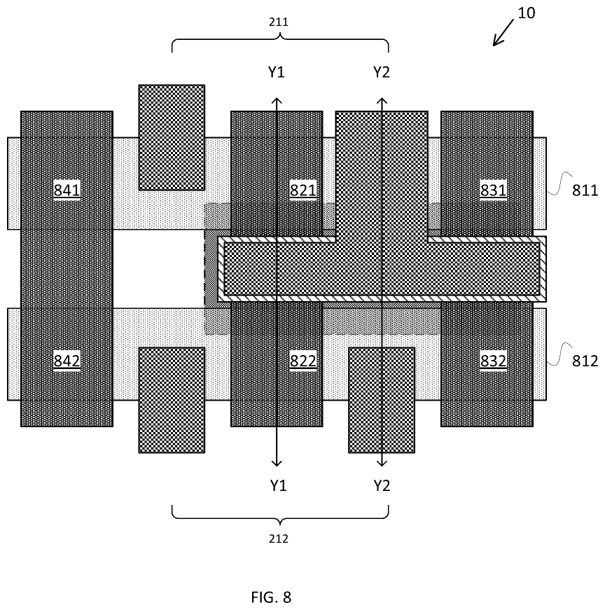

In other words, as is demonstratively illustrated in FIG. 8 of a simplified top view of the semiconductor structure 10, FIG. 1A illustrates a cross-sectional view of the semiconductor structure 10 at a cross-section made along a line Y1-Y1, which crosses a first gate 821 of a first nanosheet transistor 211 and a second gate 822 of a second nanosheet transistor 212. FIG. 1B illustrates a cross-sectional view of the semiconductor structure 10 at a cross-section made along a line Y2-Y2, which crosses a first source/drain region of the first nanosheet transistor 211 and a second source/drain region of the second nanosheet transistor 212. In FIG. 8, the semiconductor structure 10 is demonstratively illustrated to include a first and a second stack of nanosheets 811 and 812; the first and the second gate 821 and 822 (a first set of gates) of the first and the second nanosheet transistor 211 and 212 (a first set of transistors); a second set of gates 831, 832 of a second set of transistors; and a third set of gates 841, 842 of a third set of transistors. Regions between the first, the second, and the third set of gates are source/drain regions of the respective transistors.

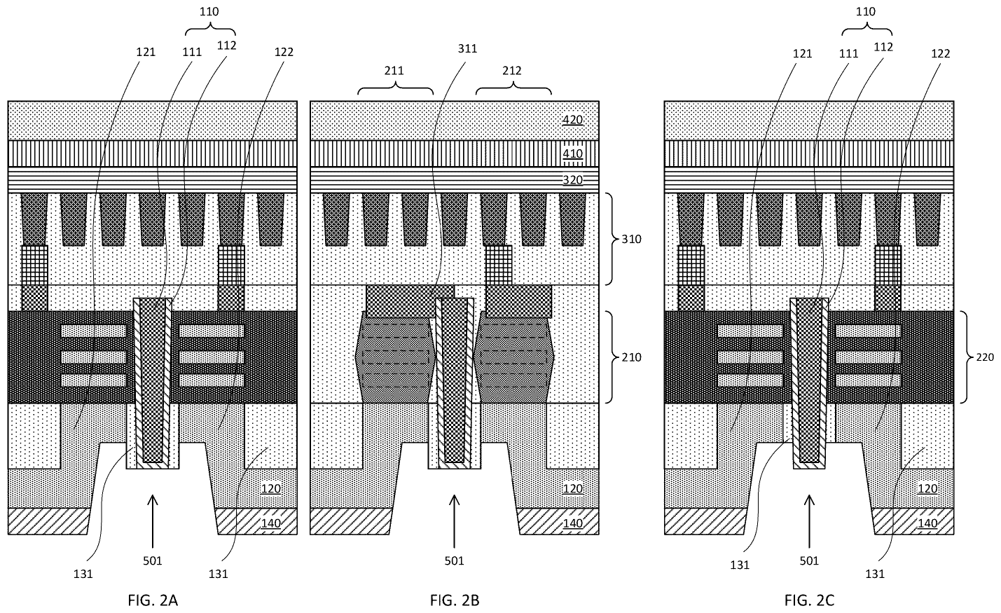

Likewise, FIGS. 2A, 2B, and 2C to FIGS. 7A, 7B, and 7C are demonstrative cross-sectional views of the semiconductor structure 10, at different manufacturing steps, and are illustrated in manners similar to FIGS. 1A, 1B, and 1C respectively.

Reference is made back to FIGS. 1A, 1B, and 1C, embodiments of present invention provide forming a semiconductor structure 10 that is demonstratively illustrated to include, for example, a first transistor such as a first nanosheet transistor 211 and a second transistor such as a second nanosheet transistor 212, although embodiments of present invention are not limited in this aspect and may be applied to other types of transistors and/or active devices. The first and the second nanosheet (NS) transistor 211 and 212 may be formed on top of a semiconductor substrate 120. For example, the first NS transistor 211 may be formed on top of a first portion 121 of the substrate 120 and the second NS transistor 212 may be formed on top of a second portion 122 of the substrate 120. One or more inter-level dielectric (ILD) layers 131 may be formed on top of the substrate 120 to surround the first and the second portion 121 and 122 of the substrate 120. In one embodiment, the one or more ILD layers 131 may be part of a shallow-trench-isolation (STI) structure embedded in the substrate 120. Additionally, a backside ILD layer 140 may be formed at a bottom surface of the substrate 120, as part of a process of forming the semiconductor structure 10 from a backside of the substrate 120.

According to one embodiment of present invention, a power rail via 110 may be formed between the first and the second NS transistor 211 and 212, in regions between a first and a second source/drain (S/D) region 210, as is illustrated in FIG. 1B, and between a first and a second gate 220, as is illustrated in FIG. 1A and FIG. 1C, of the first and the second NS transistor 211 and 212. The power rail via 110 may include a conductive core 111 and a core liner 112 that surrounds the conductive core 111 at sidewalls and a bottom or bottom surface thereof. A lower section of the power rail via 110, for example a section below the first and the second NS transistor 211 and 212, may be embedded in and surrounded by the ILD layer 131.

One or more S/D contacts and/or gate contacts may be formed to be in contact with the first and the second NS transistor 211 and 212. For example, a S/D contact 311 may be formed to be in contact with the first S/D region of the first NS transistor 211 as is illustrated in FIG. 1B. The S/D contact 311 may be conductively connected to the power rail via 110, which provides power from the BSPDN to the first NS transistor 211 through the S/D contact 311.

A back-end-of-line (BEOL) structure may be formed on top of the first and the second NS transistor 211 and 212 to provide, for example, signal routing functions and/or power through the one or more S/D contacts and gate contacts. For example, the BEOL structure may include a first metal level 310 having a plurality of metal lines and one or more contact vias. The BEOL structure may include additional metal levels 320 that are formed on top of the first metal level 310.

A layer of bonding oxide 410 may be used to attach or bond a carrier wafer 420 onto the BEOL structure such as onto the metal levels 320. The carrier wafer 420 may be bonded onto the BEOL structure such that the semiconductor structure 10 may be flipped upside-down and be processed from a backside of the substrate 120. For example, once the semiconductor substrate 120 is flipped upside-down and possibly subject to additional processing, a backside ILD layer 140 may be formed on top of the bottom surface of the substrate 120 and processing of the semiconductor structure 10 may continue.

FIGS. 2A, 2B, and 2C are demonstrative illustrations of different cross-sectional views of a semiconductor structure at a step of manufacturing thereof according to embodiments of present invention. More particularly, following the step illustrated in FIGS. 1A, 1B, and 1C, embodiments of present invention provide creating an opening, such as a trench opening 501, through the backside ILD layer 140 and the substrate 120 to expose the bottom surface of the power rail via 110. The trench opening 501, formed from the backside of the substrate 120, may be created to remove a portion of the substrate 120 directly underneath the first and the second nanosheet transistor 211 and 212, and may have a depth that goes beyond the bottom surface of the power rail via 110 such that the opening 501 may surround a lower portion of the power rail via 110. The creation of the trench opening 501 may be made, for example, through a lithographic patterning process together with one or more selective etch processes.

For example, in one embodiment as is illustrated in FIG. 2A, an etch process such as a reactive-ion-etch (RIE) process may be applied to etch through the backside ILD layer 140 and subsequently etch the substrate 120. The etch process may be selective to the power rail via 110, in particular to the core liner 112 of the power rail via 110, and to the ILD layer 131. The resulting trench opening 501 may expose a lower portion of the ILD layer 131 that surrounds a lower portion of the power rail via 110.

In another embodiment as is illustrated in FIG. 2C, the etch process may be selective to the core liner 112 of the power rail via 110 but may etch the ILD layer 131 exposed by the etch of the substrate 120. The resulting trench opening 501 may directly expose the lower portion of the power rail via 110, including sidewalls and a bottom surface thereof, that are lined by the core liner 112.

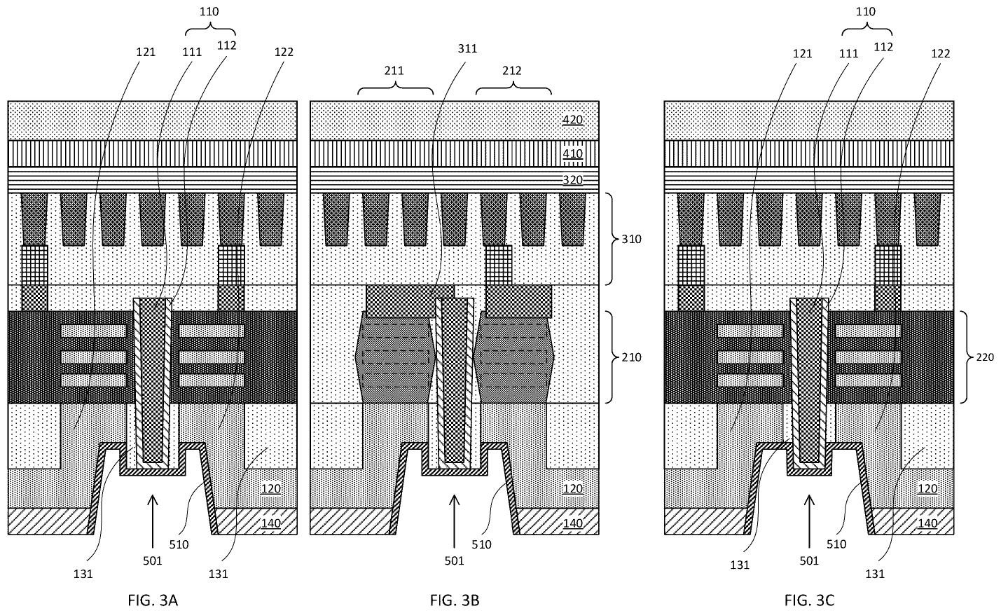

FIGS. 3A, 3B, and 3C are demonstrative illustrations of different cross-sectional views of a semiconductor structure at a step of manufacturing thereof according to embodiments of present invention. More particularly, following the step illustrated in FIGS. 2A, 2B, and 2C, embodiments of present invention provide forming a dielectric liner 510 lining sidewalls and a bottom of the trench opening 501. The dielectric liner 510 may also line, in one embodiment, sidewalls of the lower portion of the ILD layer 131 and, in another embodiment, line sidewalls of the lower portion of the power rail via 110. In this another embodiment, an upper portion of the ILD layer 131 may be directly above the dielectric liner 510, as is demonstratively illustrated in FIG. 3C, and surround a middle portion, above the lower portion, of the power rail via 110. The dielectric liner 510 may be a conformal layer of dielectric material such as, for example, silicon-nitride (SiN), silicoboron-carbonitride (SiBCN), or silicon-oxycarbonitride (SiOCN), having a thickness ranging from about 2 nm to about 15 nm.

In one embodiment, the trench opening 501 may be made sufficiently wider than a width of the power rail via 110, by removing a portion of the substrate 120 directly underneath the first and the second nanosheet transistor 211 and 212. This trench opening 501 results in a gap between a sidewall of the trench opening 501 at the substrate 120 and a sidewall of the ILD layer 131 as is illustrated in FIG. 3B, or a gap between a sidewall of the trench opening 501 at the substrate 120 and a sidewall of the power rail via 110 as is illustrated in FIG. 3C, that is not pinched off by the conformal dielectric liner 510. The un-pinched portion of gap between the dielectric liners 510 may be subsequently filled with a protective dielectric layer to protect the dielectric liner 510 during subsequent steps of processing as being described below in more details.

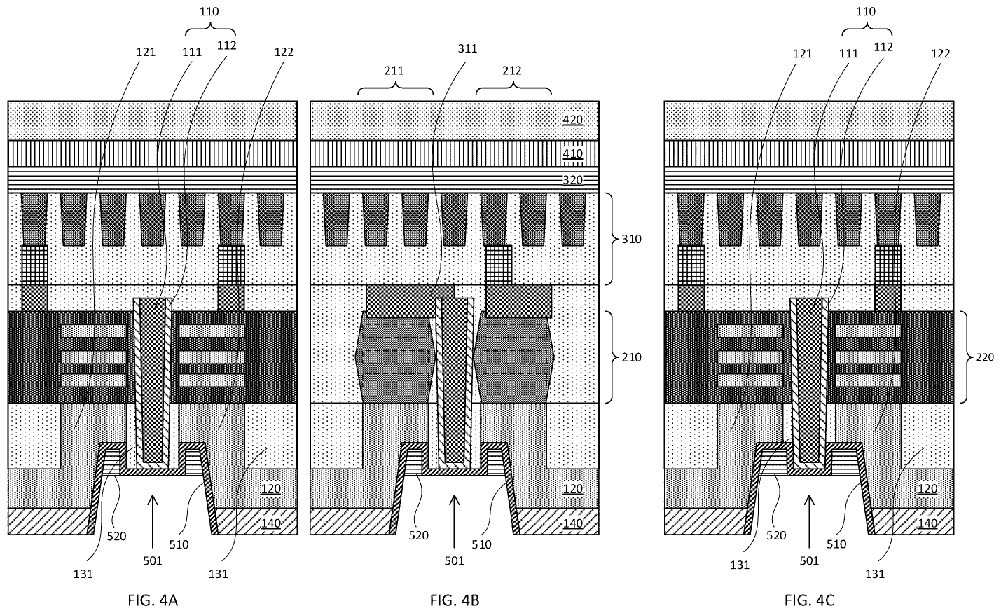

FIGS. 4A, 4B, and 4C are demonstrative illustrations of different cross-sectional views of a semiconductor structure at a step of manufacturing thereof according to embodiments of present invention. More particularly, following the step illustrated in FIGS. 3A, 3B, and 3C, embodiments of present invention provide filling the trench opening 501, on top of the dielectric liner 510 at a bottom and sidewalls thereof, with a protective dielectric material. The protective dielectric material may be, for example, SiN, SiBCN, or SiOCN and may be materially different from the dielectric liner 510 to have an etch selectivity that is different from that of the dielectric liner 510. The protective dielectric material may be formed through a deposition process such as, for example, a chemical-vapor-deposition (CVD) process, a plasma-enhanced CVD (PECVD) process, a physical-vapor-deposition (PVD) process, and/or an atomic-layer-deposition (ALD) process.

Following the deposition, a chemical-mechanical-polishing (CMP) process may be applied to planarize a bottom surface (which is a top surface from the standpoint of process considering that the substrate is now being flipped upside-down) of the protective dielectric material. Next, a recessing process may be applied to the protective dielectric material until a portion of the dielectric liner 510 covering a bottom surface of the power rail via 110 is exposed. The recess of the protective dielectric material results in a protective dielectric layer 520 surrounding sidewalls of a lower portion, or a first portion, of the power rail via 110 either indirectly via a lower portion of the ILD layer 131 as is illustrated in FIG. 4A, or directly as is illustrated in FIG. 4C. In other words, the protective dielectric layer 520 may be formed in the un-pinched portion of the gap and between the dielectric liners 510, resulting in having both an outer sidewall and an inner sidewall that are covered by the dielectric liner 510. A top surface of the protective dielectric layer 520 is covered by the dielectric liner 510.

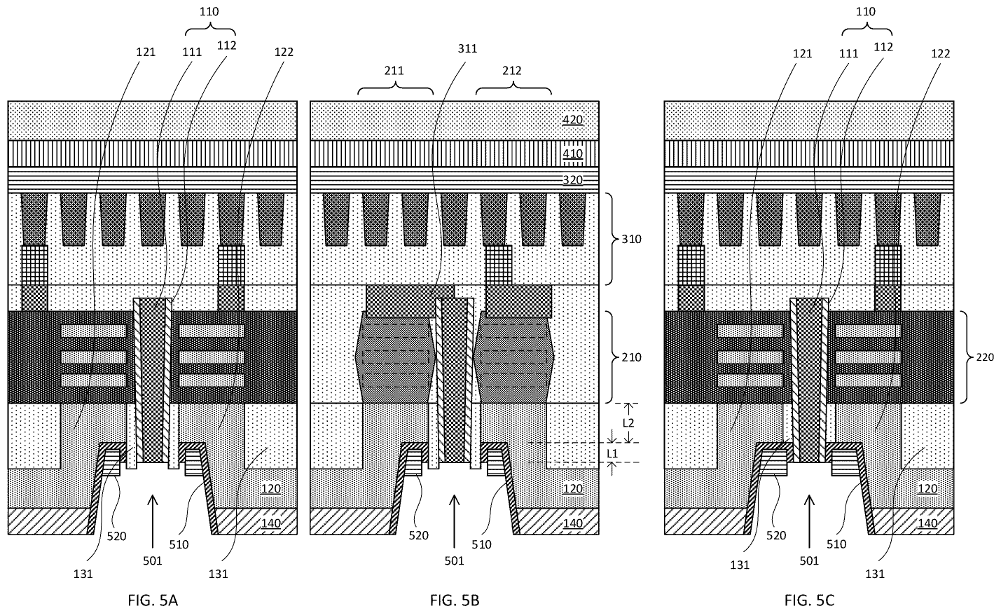

FIGS. 5A, 5B, and 5C are demonstrative illustrations of different cross-sectional views of a semiconductor structure at a step of manufacturing thereof according to embodiments of present invention. More particularly, following the step illustrated in FIGS. 4A, 4B, and 4C, embodiments of present invention provide removing the exposed portion of the dielectric liner 510 that are directly underneath the power rail via 110 or more particularly underneath the core liner 112 of the power rail via 110. The removal process may be, for example, a selective and/or directional etch process such as a reactive-ion-etch (RIE) process. The RIE process may etch away or remove the horizontal portion of the dielectric liner 510 while leaving the vertical portion of the dielectric liner 510, such as those at the sidewalls of the trench opening 501 next to the substrate 120, substantially unaffected.

In the meantime, the protective dielectric layer 520 may protect portions of the dielectric liner 510 that are at a level above the bottom surface of the power rail via 110 during the selective etch process. For example, a portion of the dielectric liner 510 next to sidewalls of the power rail via 110 or sidewalls of the ILD layer 131 as well as a portion of the dielectric liner 510 at the bottom of the protective dielectric layer 520 may be protected. Here, it is noted that although the portion of the dielectric liner 510 is, from a process standpoint in view of how the protective dielectric layer 520 is formed, at the bottom of the protective dielectric layer 520, structurally the portion of the dielectric liner 510 protected by the protective dielectric layer 520 is at a top of the protective dielectric layer 520, as they are demonstratively illustrated in FIG. 5A and 5C.

Following the removal of the exposed horizontal portion of the dielectric liner 510, the core liner 112 of the power rail via 110 may be exposed, which may subsequently be removed in an etch process that is selective to the ILD layer 131, to the protective dielectric layer 520, and to the dielectric liner 510. The selective etch process may expose a bottom surface of the conductive core 111 of the power rail via 110. The bottom surface of the conductive core 111 may therefore be at a level above a bottom surface of the ILD layer 131, which was left substantially unaffected or unetched by the nature of selectivity of the etch process.

A lower portion L1 of the power rail via 110 may be surrounded directly or indirectly by the dielectric liner 510 and the protective dielectric layer 520, while a middle portion L2 of the power rail via 110 may be directly surrounded by the ILD layer 131.

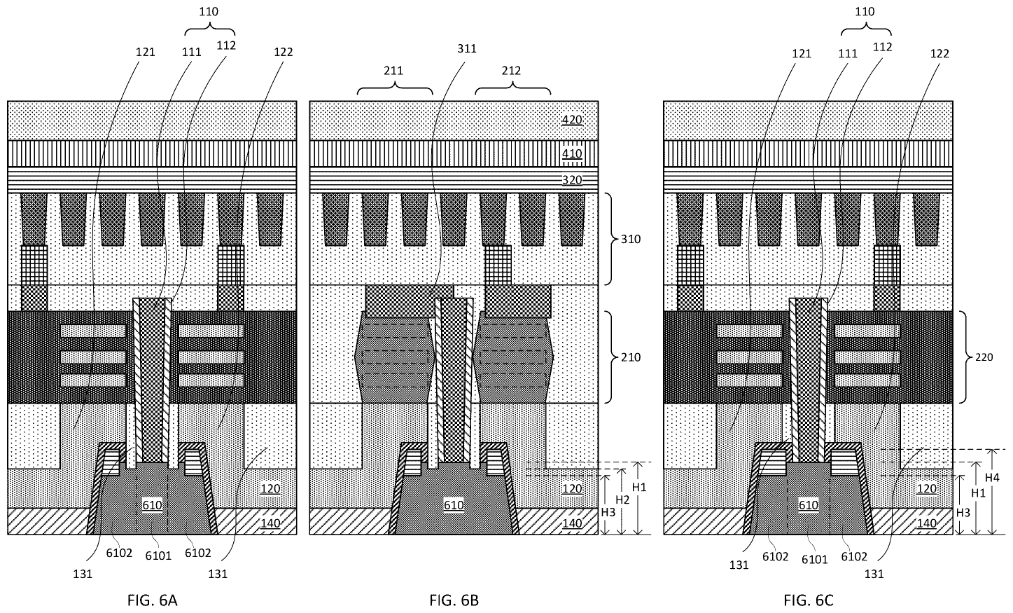

FIGS. 6A, 6B, and 6C are demonstrative illustrations of different cross-sectional views of a semiconductor structure at a step of manufacturing thereof according to embodiments of present invention. More particularly, following the step illustrated in FIGS. 5A, 5B, and 5C, embodiments of present invention provide filling the trench opening 501 with a conductive material such as, for example, copper (Cu), aluminum (Al), ruthenium (Ru), tungsten (W), cobalt (Co) thereby forming a backside via 610. Filling the trench opening 501 with the conductive material may be made through a deposition process such as a CVD process, a PECVD process, a PVD process, an ALD process, and may be made by a plating process as well.

The backside via 610 may have a first portion 6101 centrally in the middle and a second portion 6102 surrounding the first portion 6101. The first portion 6101 of the backside via 610 may be directly underneath, thereby contacting, the power rail via 110 and the second portion 6102 of the backside via 610 may be underneath, at least partially, the protective dielectric layer 520 as is demonstratively illustrated in FIGS. 6A, 6B, and 6C. A top surface of the first portion 6101 of the backside via 610 may be at a level H1 that is above or higher than a level H3 of a top surface of the second portion 6102 of the backside via 610, as are demonstratively illustrated in FIGS. 6A, 6B, and 6C, and above or higher than a level H2 of a bottom surface of the ILD layer 131, as is demonstratively illustrated in FIGS. 6A and 6B, where the ILD layer 131 surrounds the entire lower section of the power rail via 110 below the first and the second NS transistor 211 and 212.

In contrast, in the embodiment illustrated in FIG. 6C, a lower portion (or a first portion) of the power rail via 110 is directly surrounded by the dielectric liner 510 while a middle portion (or a second portion) of the power rail via 110, directly above lower portion, is surrounded by the ILD layer 131. In this embodiment, the ILD layer 131 is directly above the dielectric liner 510 to have a bottom surface that is above a top surface of the first portion 6101 of the backside via 610 that contacts the conductive core 111 of the power rail via 110. In the meantime, sidewalls of the backside via 610 and in particular sidewalls of the second portion 6102 of the backside via 610 is surrounded by the dielectric liner 510.

In the meantime, both a top surface and outer sidewalls of the protective dielectric layer 520 are covered by the dielectric liner 510. The top surface of the protective dielectric layer 520 may be at a level H4 this is higher than the top surface of the first portion 6101 of the backside via 610, that is, higher than a bottom surface of the power rail via 110.

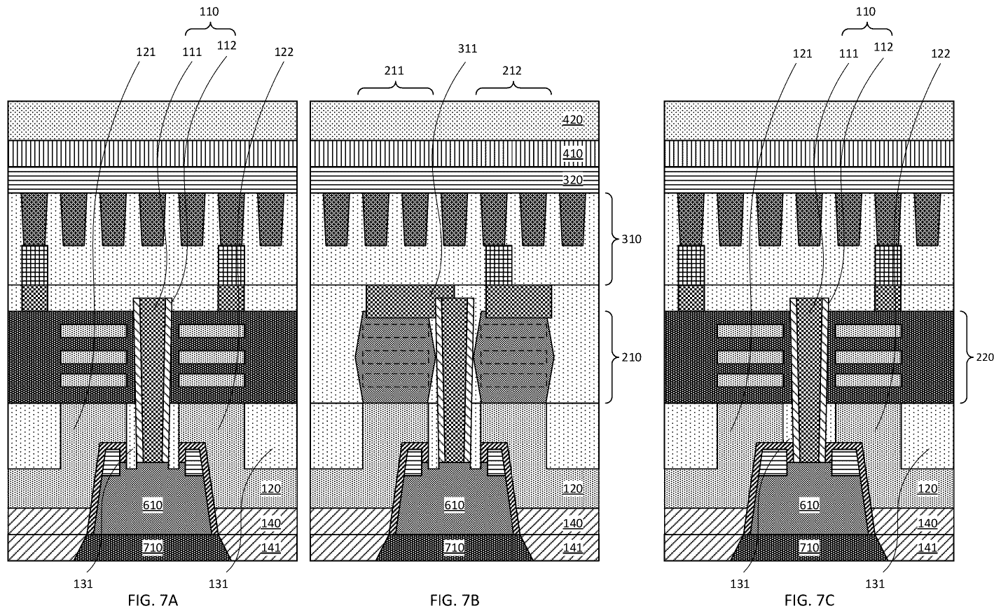

FIGS. 7A, 7B, and 7C are demonstrative illustrations of different cross-sectional views of a semiconductor structure at a step of manufacturing thereof according to embodiments of present invention. More particularly, following the step illustrated in FIGS. 6A, 6B, and 6C, embodiments of present invention provide forming backside power rail that provides power to the backside via. For example, a dielectric layer 141 may first be deposited on top of the backside ILD layer 140. One or more openings may be created in the dielectric layer 141, for example, through a lithographic patterning and etch process, to expose one or more backside vias such as the backside via 610. Conductive material, such as Cu, Al, Ru, W, Co, may subsequently be used to fill the openings thereby forming a backside power rail 710 that is in contact with the backside via 610.

FIG. 8 is a demonstrative illustration of a simplified top view of the semiconductor structure 10 illustrating cross-section location along the line Y1-Y1 shown in FIGS. 1A, 2A, 3A, 4A, 5A, 6A, and 7A, and cross-section location along the line Y2-Y2 shown in FIGS. 1B, 2B, 3B, 4B, 5B, 6B, and 7B.

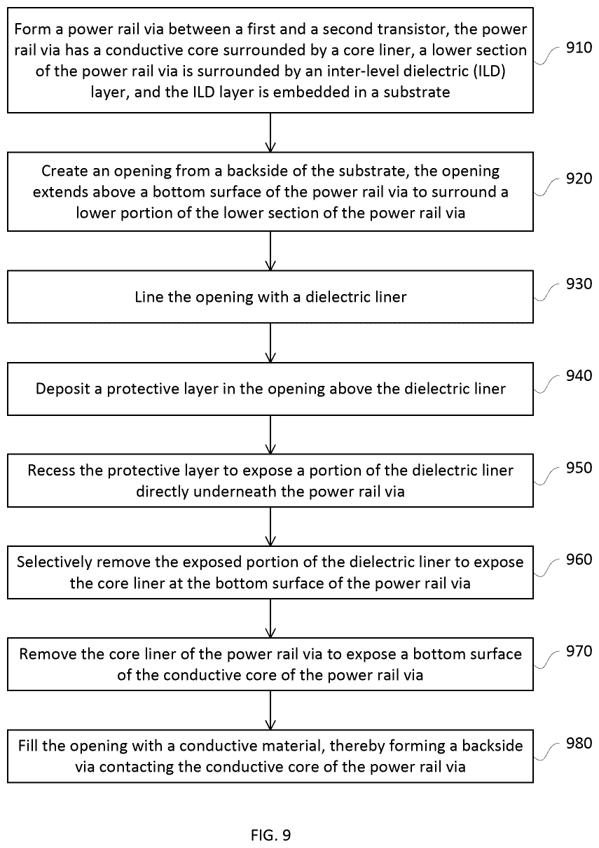

FIG. 9 is a demonstrative illustration of a flow-chart of a method of manufacturing a semiconductor structure according to embodiments of present invention. The method includes (910) forming a power rail via between a first and a second transistor, where the power rail via has a conductive core surrounded by a core liner, a lower section of the power rail via is surrounded by an inter-level dielectric (ILD) layer, and the ILD layer is embedded in a substrate; (920) creating an opening in the substrate from a backside of the substrate, where the opening extends above a bottom surface of the power rail via to surround a lower portion of the lower section of the power rail via; (930) lining the opening with a dielectric liner; (940) depositing a protective layer in the opening above the dielectric liner; (950) recessing the protective layer to expose a portion of the dielectric liner directly underneath the power rail via; (960) selectively removing the exposed portion of the dielectric liner to expose the core liner at the bottom surface of the power rail via; (970) removing the core liner of the power rail via to expose a bottom surface of the conductive core of the power rail via; and (980) filling the opening with a conductive material, thereby forming a backside via contacting the conductive core of the power rail via.

Various examples may possibly be described by one or more of the following features in the following numbered clauses:

Clause 1: A semiconductor structure comprising a first and a second transistor; a power rail via between the first and the second transistor; and a backside via below the power rail via and below the first and the second transistor, wherein the backside via has a first portion directly underneath and contacting the power rail via and a second portion surrounding the first portion, and a top surface of the first portion is above a top surface of the second portion.

Clause 2: The semiconductor structure of clause 1, wherein the top surface of the second portion of the backside via is covered by a protective dielectric layer; and a sidewall of the backside via and an outer sidewall of the protective dielectric layer are covered by a dielectric liner.

Clause 3: The semiconductor structure of clause 2, wherein a lower portion of the power rail via that directly contacts the backside via is directly surrounded by an inter-level dielectric (ILD) layer, and a portion of the ILD layer is surrounded by the dielectric liner.

Clause 4: The semiconductor structure of clause 3, wherein the top surface of the first portion of the backside via is higher than a bottom surface of the ILD layer.

Clause 5: The semiconductor structure of clause 2, wherein the power rail via has a lower portion directly contacting the backside via and a middle portion above the lower portion of the power rail via, the lower portion of the power rail via is directly surrounded by the dielectric liner, and the middle portion of the power rail via is directly surrounded by an inter-level dielectric (ILD) layer, wherein the ILD layer is above the dielectric liner and has a bottom surface that is above the top surface of the first portion of the backside via.

Clause 6: The semiconductor structure of clause 2, wherein a top surface of the protective dielectric layer is above the top surface of the first portion of the backside via and is covered by the dielectric liner.

Clause 7: The semiconductor structure of clause 1, wherein the power rail via comprises a conductive core and a core liner, the core liner lines the conductive core at a sidewall of the power rail via.

Clause 8: The semiconductor structure of clause 1, wherein the first and the second transistor include, respectively, a first and a second gate and, respectively, a first and a second source/drain region, and wherein the power rail via extends from a first region between the first and the second gate and to a second region between the first and the second source/drain region.

Clause 9: A method of forming a semiconductor structure comprising forming a power rail via between a first and a second transistor, the power rail via including a conductive core surrounded by a core liner, a lower section of the power rail via being surrounded by an inter-level dielectric (ILD) layer, the ILD layer being embedded in a substrate; creating an opening in the substrate from a backside of the substrate, the opening extends above a bottom surface of the power rail via to surround a lower portion of the lower section of the power rail via; lining the opening with a dielectric liner; removing the core liner of the power rail via to expose a bottom surface of the conductive core of the power rail via; and filling the opening with a conductive material, thereby forming a backside via contacting the conductive core of the power rail via.

Clause 10: The method of clause 9, further comprising depositing a protective layer in the opening above the dielectric liner; recessing the protective layer to expose a portion of the dielectric liner directly underneath the power rail via; and selectively removing the exposed portion of the dielectric liner to expose the core liner at the bottom surface of the conductive core of the power rail via.

Clause 11: The method of clause 10, wherein the selectively removal of the exposed portion of the dielectric liner also exposes a bottom surface of the ILD layer.

Clause 12: The method of clause 9, wherein creating the opening comprises removing a portion of the substrate surrounding the ILD layer such that the dielectric liner lines a portion of sidewalls of the ILD layer.

Clause 13: The method of clause 9, wherein creating the opening comprises removing a portion of the substrate and a portion of the ILD layer such that the dielectric liner lines sidewalls of a lower portion of the power rail via.

Clause 14: The method of clause 9, wherein creating the opening comprises removing a portion of the substrate that is directly underneath the first and the second transistor.

Clause 15: A semiconductor structure comprising a first and a second transistor; a power rail via between the first and the second transistor, the power rail via including a conductive core and a core liner, the core liner lining the conductive core at a sidewall of the power rail via; and a backside via below the power rail via and below the first and the second transistor, wherein the backside via has a first portion directly contacting the conductive core of the power rail via and a second portion around the first portion, and a top surface of the first portion is above a top surface of the second portion.

Clause 16: The semiconductor structure of clause 15, wherein the top surface of the second portion of the backside via is covered by a protective dielectric layer; and a sidewall of the backside via and a sidewall of the protective dielectric layer are covered by a dielectric liner.

Clause 17: The semiconductor structure of clause 16, wherein a lower portion of the power rail via that contacts the backside via is surrounded by an inter-level dielectric (ILD) layer, and a portion of the ILD layer is surrounded by the dielectric liner.

Clause 18: The semiconductor structure of clause 17, wherein the top surface of the first portion of the backside via is higher than a bottom surface of the ILD layer.

Clause 19: The semiconductor structure of clause 16, wherein the lower section of the power rail via has a first portion directly contacting the backside via and a second portion above the first portion of the power rail via, the core liner of the first portion of the power rail via is directly surrounded by the dielectric liner, and the core liner of the second portion of the power rail via is directly surrounded by an inter-level dielectric (ILD) layer, wherein the ILD layer is above the dielectric liner and has a bottom surface that is above the top surface of the first portion of the backside via.

Clause 20: The semiconductor structure of clause 16, wherein a top surface of the protective dielectric layer is above the top surface of the first portion of the backside via and is covered by the dielectric liner.

It is to be understood that the exemplary methods discussed herein may be readily incorporated with other semiconductor processing flows, semiconductor devices, and integrated circuits with various analog and digital circuitry or mixed-signal circuitry. In particular, integrated circuit dies can be fabricated with various devices such as field-effect transistors, bipolar transistors, metal-oxide-semiconductor transistors, diodes, capacitors, inductors, etc. An integrated circuit in accordance with the present invention can be employed in applications, hardware, and/or electronic systems. Suitable hardware and systems for implementing the invention may include, but are not limited to, personal computers, communication networks, electronic commerce systems, portable communications devices (e.g., cell phones), solid-state media storage devices, functional circuitry, etc. Systems and hardware incorporating such integrated circuits are considered part of the embodiments described herein. Given the teachings of the invention provided herein, one of ordinary skill in the art will be able to contemplate other implementations and applications of the techniques of the invention.

Accordingly, at least portions of one or more of the semiconductor structures described herein may be implemented in integrated circuits. The resulting integrated circuit chips may be distributed by the fabricator in raw wafer form (that is, as a single wafer that has multiple unpackaged chips), as a bare die, or in a packaged form. In the latter case the chip may be mounted in a single chip package (such as a plastic carrier, with leads that are affixed to a motherboard or other high-level carrier) or in a multichip package (such as a ceramic carrier that has surface interconnections and/or buried interconnections). In any case the chip may then be integrated with other chips, discrete circuit elements, and/or other signal processing devices as part of either an intermediate product, such as a motherboard, or an end product. The end product may be any product that includes integrated circuit chips, ranging from toys and other low-end applications to advanced computer products having a display, a keyboard or other input device, and a central processor.

The descriptions of various embodiments of present invention have been presented for the purposes of illustration and they are not intended to be exhaustive and present invention are not limited to the embodiments disclosed. The terminology used herein was chosen to best explain the principles of the embodiments, practical application or technical improvement over technologies found in the marketplace, and to enable others of ordinary skill in the art to understand the embodiments disclosed herein. Many modifications, substitutions, changes, and equivalents will now occur to those of ordinary skill in the art. Such changes, modification, and/or alternative embodiments may be made without departing from the spirit of present invention and are hereby all contemplated and considered within the scope of present invention. It is, therefore, to be understood that the appended claims are intended to cover all such modifications and changes as fall within the spirit of the invention.

What is claimed is:

1. A semiconductor structure comprising:
a first and a second transistor;
a power rail via between the first and the second transistor; and
a backside via below the power rail via and below the first and the second transistor,
wherein the backside via has a first portion directly underneath and contacting the power rail via and a second portion surrounding the first portion, and a top surface of the first portion is above a top surface of the second portion.

2. The semiconductor structure of claim 1, wherein the top surface of the second portion of the backside via is covered by a protective dielectric layer; and a sidewall of the backside via and an outer sidewall of the protective dielectric layer are covered by a dielectric liner.

3. The semiconductor structure of claim 2, wherein a lower portion of the power rail via directly contacting the backside via is directly surrounded by an inter-level dielectric (ILD) layer, and a portion of the ILD layer is surrounded by the dielectric liner.

4. The semiconductor structure of claim 3, wherein the top surface of the first portion of the backside via is higher than a bottom surface of the ILD layer.

5. The semiconductor structure of claim 2, wherein the power rail via has a lower portion directly contacting the backside via and a middle portion above the lower portion of the power rail via, the lower portion of the power rail via is directly surrounded by the dielectric liner, and the middle portion of the power rail via is directly surrounded by an inter-level dielectric (ILD) layer, wherein the ILD layer is above the dielectric liner and has a bottom surface that is above the top surface of the first portion of the backside via.

6. The semiconductor structure of claim 2, wherein a top surface of the protective dielectric layer is above the top surface of the first portion of the backside via and is covered by the dielectric liner.

7. The semiconductor structure of claim 1, wherein the power rail via comprises a conductive core and a core liner, the core liner lines the conductive core at a sidewall of the power rail via.

8. The semiconductor structure of claim 1, wherein the first and the second transistor include, respectively, a first and a second gate and, respectively, a first and a second source/drain region, and wherein the power rail via extends from a first region between the first and the second gate and to a second region between the first and the second source/drain region.

9. A method of forming a semiconductor structure comprising:
forming a power rail via between a first and a second transistor, the power rail via including a conductive core surrounded by a core liner, a lower section of the power rail via being surrounded by an inter-level dielectric (ILD) layer, the ILD layer being embedded in a substrate;
creating an opening in the substrate from a backside of the substrate, the opening extends above a bottom surface of the power rail via to surround a lower portion of the lower section of the power rail via;
lining the opening with a dielectric liner;
removing the core liner of the power rail via to expose a bottom surface of the conductive core of the power rail via; and
filling the opening with a conductive material, thereby forming a backside via contacting the conductive core of the power rail via.

10. The method of claim 9, further comprising:
depositing a protective layer in the opening above the dielectric liner;
recessing the protective layer to expose a portion of the dielectric liner directly underneath the power rail via; and
selectively removing the exposed portion of the dielectric liner to expose the core liner at the bottom surface of the conductive core of the power rail via.

11. The method of claim 10, wherein the selectively removal of the exposed portion of the dielectric liner also exposes a bottom surface of the ILD layer.

12. The method of claim 9, wherein creating the opening comprises removing a portion of the substrate surrounding the ILD layer such that the dielectric liner lines a portion of sidewalls of the ILD layer.

13. The method of claim 9, wherein creating the opening comprises removing a portion of the substrate and a portion of the ILD layer such that the dielectric liner lines sidewalls of a lower portion of the power rail via.

14. The method of claim 9, wherein creating the opening comprises removing a portion of the substrate that is directly underneath the first and the second transistor.

15. A semiconductor structure comprising:
a first and a second transistor;
a power rail via between the first and the second transistor, the power rail via including a conductive core and a core liner, the core liner lining the conductive core at a sidewall of the power rail via; and
a backside via below the power rail via and below the first and the second transistor,
wherein the backside via has a first portion directly contacting the conductive core of the power rail via and a second portion around the first portion, and a top surface of the first portion is above a top surface of the second portion.

16. The semiconductor structure of claim 15, wherein the top surface of the second portion of the backside via is covered by a protective dielectric layer; and a sidewall of the backside via and a sidewall of the protective dielectric layer are covered by a dielectric liner.

17. The semiconductor structure of claim 16, wherein a lower portion of the power rail via that contacts the backside via is surrounded by an inter-level dielectric (ILD) layer, and a portion of the ILD layer is surrounded by the dielectric liner.

18. The semiconductor structure of claim 17, wherein the top surface of the first portion of the backside via is higher than a bottom surface of the ILD layer.

19. The semiconductor structure of claim 16, wherein the lower section of the power rail via has a first portion directly contacting the backside via and a second portion above the first portion of the power rail via, the core liner of the first portion of the power rail via is directly surrounded by the dielectric liner, and the core liner of the second portion of the power rail via is directly surrounded by an inter-level dielectric (ILD) layer, wherein the ILD layer is above the dielectric liner and has a bottom surface that is above the top surface of the first portion of the backside via.

20. The semiconductor structure of claim 16, wherein a top surface of the protective dielectric layer is above the top surface of the first portion of the backside via and is covered by the dielectric liner.
